(19) United States
(12) Patent Application Publication
(10) Pub. No.: US 2016/0351330 A1
(43) Pub. Date: Dec. 1, 2016

(54) MULTI-LAYER CAPACITOR HAVING UPPER AND LOWER PORTIONS WITH DIFFERENT DIELECTRIC LAYER MATERIALS TO REDUCE ACOUSTIC VIBRATION

(71) Applicant: APPLE INC., Cupertino, CA (US)

(72) Inventors: Zhong-Qing Gong, Fremont, CA (US); Kevin R. Richardson, Sunnyvale, CA (US); Connor R. Duke, Sunnyvale, CA (US); Yanchu Xu, San Jose, CA (US); Benjamin A. Bard, San Jose, CA (US)

(21) Appl. No.: 14/721,956

(22) Filed: May 26, 2015

(51) Int. Cl. H01G 4/12; H05K 3/30; H01G 4/236; H05K 1/18; H01G 4/30; H01G 4/012

(52) U.S. Cl. CPC H01G 4/1227; H01G 4/30; H01G 4/012; H01G 4/236; H05K 1/181; H05K 3/303; H05K 2201/10015

(57) ABSTRACT

A multi-layer capacitor such as a multi-layer-ceramic-capacitor (MLCC) has upper and lower dielectric layers separating upper and lower electrode layers, where the lower dielectric layers have a lower dielectric constant than the upper dielectric layers to reduce piezoelectric effect driven capacitor reaction forces on a printed circuit board (PCB) on which the capacitor is mounted. Such an MLCC may include the upper dielectric and electrode layers in a top portion of the MLCC; and the lower dielectric and electrode layers in a bottom portion of the MLCC. A bottom portion of the MLCC may be mounted on a PCB. As an example, the dielectric constant value of the lower dielectric layers may be between 1.5 and 3.5 times less than that of the upper dielectric layers to reduce piezoelectric effect driven capacitor reaction forces in the audio range of human hearing. Other embodiments are also described and claimed.

### FIELD

Embodiment of the present invention relate to a multi-layer capacitor having upper and lower portions with upper and lower dielectric layers separating upper and lower electrode layers, where the lower dielectric layers have the same vertical thickness as, but a lower dielectric constant than the upper dielectric layers to reduce piezoelectric effect driven capacitor reaction forces on a printed circuit board (PCB) on which the capacitor is mounted.

### BACKGROUND

In order to increase the capacitance of a multi-layer capacitor such as a multi-layer-ceramic-capacitor (MLCC), the number of dielectric layers in the MLCC can be increased. However, as the number of dielectric layers increases significantly, the dielectric layer thickness between two adjacent electrode layers decreases to sub micrometer scale. In some cases, the dielectric layers are made from ferroelectric electrostrictive materials, such as BaTiO3, which is layered between conductive electrode layers. As the dielectric layer thickness decreases, the voltage gradient in the dielectric layer can polarize the dielectric materials and then induce the dielectric layer to deform due to piezoelectric effects. The deformed MLCC can generate a reaction force, which acts on a PCB board upon which the MLCC is mounted. The PCB board can vibrate due to the capacitor force and induce an acoustic noise in the PCB in the human hearing range. It may be desirable to reduce this acoustic noise in electronic devices having the MLCC.

### SUMMARY

Embodiments of the present invention relate to a multi-layer capacitor having upper and lower portions with different dielectric layer materials to reduce acoustic vibration. Some embodiments include a multi-layer-ceramic-capacitor (MLCC) having upper and lower dielectric layers separating upper and lower electrode layers, where the lower dielectric layers have the same vertical thickness as, but a lower dielectric constant than the upper dielectric layers to reduce piezoelectric effect driven capacitor reaction forces on a printed circuit board (PCB) on which the capacitor is mounted.

In some embodiments, a MLCC includes upper electrode layers in a top portion of the MLCC, with a first set of the upper electrode layers connected to a first terminal of the MLCC via an upper portion of a first conductive region that extends along a left side of the MLCC. A second set of the upper electrode layers are connected to a second terminal of the MLCC via an upper portion of a second conductive region that extends along a right side of the MLCC. Each of a first set of dielectric layers separates an adjacent pair of one of the first set upper electrode layers and one of the second set of the upper electrode layers.

The lower electrode layers, in a bottom portion of the capacitor, include a first set of the lower electrode layers that are connected to the first terminal via a lower portion of the first conductive region, and a second set of the lower electrode layers that are connected to the second terminal via a lower portion of the second conductive region. Each of a second set of dielectric layers, having a same vertical thickness as the first set of dielectric layers, separates an adjacent pair of one of the first set of lower electrode layers and one of the second set of the lower electrode layers. A dielectric constant value of the second set of dielectric layers is less than a dielectric constant value of the first set of dielectric layers. The MLCC may be mounted on a printed circuit board (PCB), via conductive bonds that join the first and second terminals to respective contacts formed in the PCB.

In some cases, the dielectric constant value of the second set of dielectric layers of the bottom portion of the MLCC (and optionally a height of the lower portion of the MLCC) is selected to reduce a capacitor reaction force on or vibration of the PCB (which may be due to piezoelectric effects in the dielectric layers of the MLCC due to a voltage gradient across them.) This may advantageously reduce an acoustic noise or vibration of the PCB in the human hearing range.

In certain embodiments, the lower portion has a height equal to between 20 and 30 percent of a total height of the MLCC; the dielectric constant value of the first set of dielectric layers (in the bottom portion of the MLCC) is between 1000 and 3000 while the dielectric constant value of the second set of dielectric layers (in the top portion of the MLCC) is between 100 and 1000.

### BRIEF DESCRIPTION OF THE DRAWINGS

The embodiments of the invention are illustrated by way of example and not by way of limitation in the figures of the accompanying drawings in which like references indicate similar elements. It should be noted that references to “an” or “one” embodiment of the invention in this disclosure are not necessarily to the same embodiment, and they mean at least one.

FIGS. 1A and 1B show an example of a multi-layer capacitor having upper and lower dielectric layers separating upper and lower electrode layers, where the lower dielectric layers have a lower dielectric constant than the upper dielectric layers.

FIG. 2A is an example of a plot of reduction in capacitor reaction force versus the percentage of height H3 of the lower portion to total height H1 of a multi-layer capacitor.

FIG. 2B is an example of a plot of reduction in capacitor reaction force versus the percentage of dielectric constant K1 of upper portion dielectric layers to constant K2 of the lower portion dielectric layers of a multi-layer capacitor.

FIG. 3 shows an example of capacitor reaction force for an example of a regular uniform dielectric layer capacitor and an example of a bi-material dielectric layer MLCC.

FIG. 4 shows an example of PCB board frequency response for an example of a regular uniform dielectric layer capacitor and an example of a bi-material dielectric layer MLCC.

FIG. 5 shows an example of instances of portable consumer electronics devices in which embodiments of a multi-layer capacitor may be implemented.

### DETAILED DESCRIPTION

Multi-layer-ceramic-capacitors (MLCCs) are widely used on printed circuit board (PCB) in the high tech industry, especially in handheld devices. For example, a MLCC may be used to filter out noise from power and ground signals transmitted through vias of or along traces of a PCB or of a processor package substrate. In some cases, uses may include as a decoupling capacitor to filter out alternating current (AC) signals from a direct current (DC) signal, such as a power or ground signal.

Such an MLCC may have ferroelectric electrostrictive material dielectric layers with a thickness between two adjacent electrode layers in a sub micrometer scale. In such cases, the voltage gradient in the dielectric layer can polarize the dielectric materials and then induce the dielectric layer to deform due to piezoelectric effects. The deformed MLCC can generate a reaction force, which acts on a PCB board upon which the MLCC is mounted. The PCB board can vibrate due to the capacitor force and induce an acoustic noise in the PCB in the human hearing range. It may be desirable to reduce this acoustic noise in electronic devices having the MLCC. This reduction can allow the user to better enjoy use of the device without hearing the noise or vibration. In some cases, this reduces the noise or vibration heard by the user while listening to a phone call or audio stream. In some cases, this reduces the noise or vibration heard by a call recipient or other device connected to the user's device by a wired or wireless connection, such as for a call recipient of a phone call with the user.

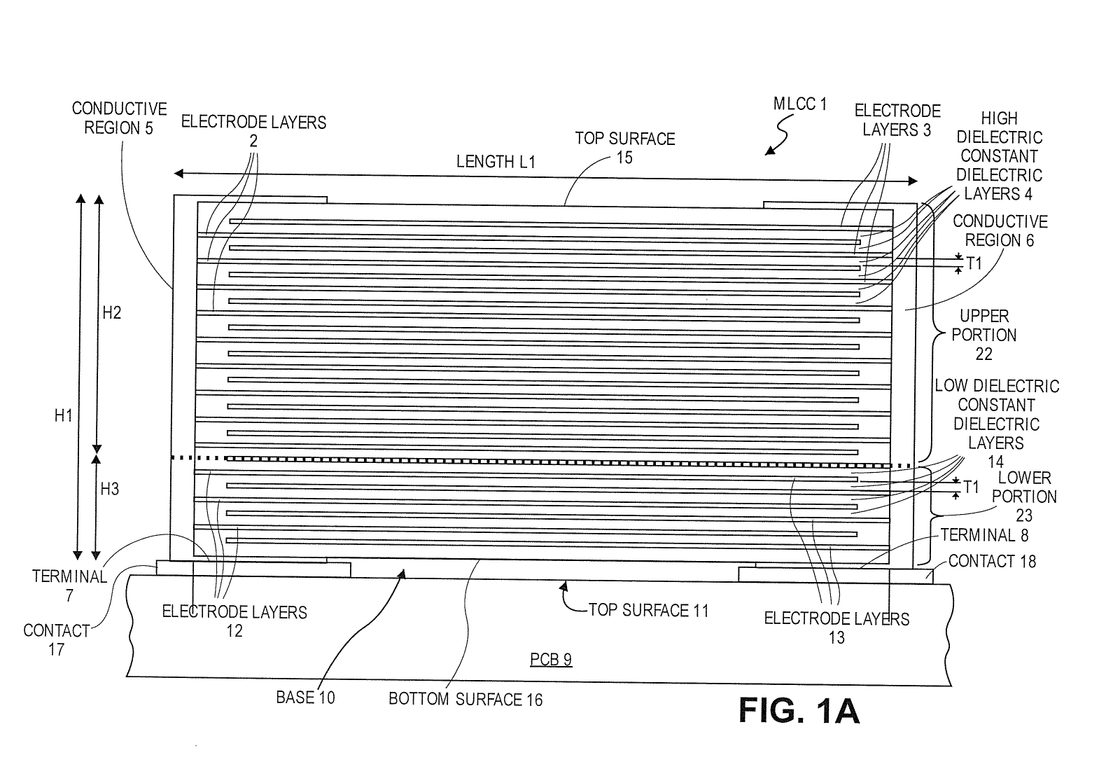

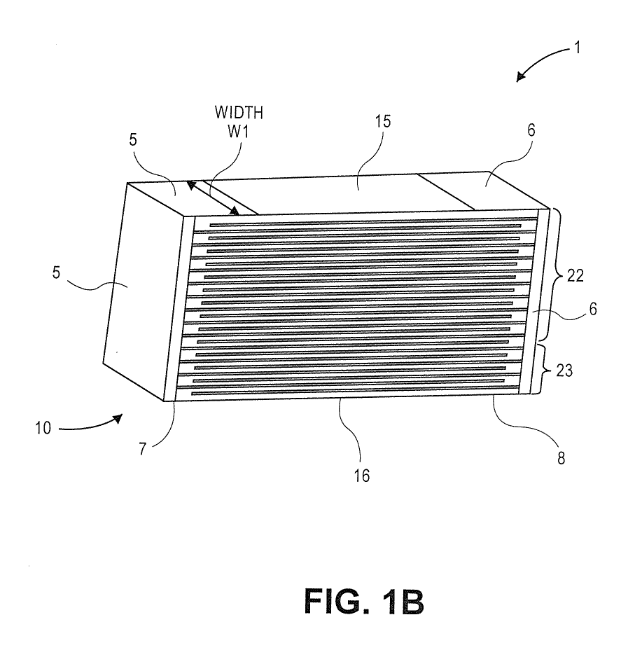

FIGS. 1A and 1B show an example of a multi-layer capacitor as MLCC 1, having upper and lower dielectric layers separating upper and lower electrode layers, where the lower dielectric layers have the same vertical thickness as, but a lower dielectric constant than the upper dielectric layers. FIGS. 1A and 1B show MLCC 1 having first (e.g., upper) conductive electrode layers (e.g., set of upper layers 2 and 3) in top portion 22 of the MLCC. The upper layers 2 are directly connected to first terminal 7 (and not second terminal 8) of the MLCC. This direct connection may be a direct connection via (e.g., attached or electrically connected through) an upper portion of first conductive region 5 that extends along a left side of the MLCC. In some cases, layers 2 are attached to region 5, which is attached to terminal 7. Such attachment may include attachment using solder, solder filler, resin, adhesive, by other materials, by pressure attachment, by heat attachment, by attachment during fabrication of layers of the MLCC as known in the art to attach such layers, regions and/or terminals of a MLCC.

The upper layers 3 are directly connected to second terminal 8 (and not the first terminal 7) of the MLCC. This direct connection may be a direct connection via an upper portion of second conductive region 6 that extends along a right side of the MLCC. In some cases, layers 3 are attached to region 6, which is attached to terminal 8. Such attachment may include a similar type of attachment as described above for the upper layers 2, region 5 and terminal 7. The vertical order or sequence of the upper layers 2 and 3 may be interleaved or alternating as shown in the figure. They may be vertically interleaved or alternating with one dielectric layer 4 separating (or between each of) the layers 2 and 3 (e.g., each of an adjacent pair of layer 2 and 3).

MLCC 1 has upper insulating high dielectric constant dielectric layers 4 separating the first electrode layers (e.g., disposed between layers 2 and 3), such as by having layers 4 between pairs of the first set 2 and second set 3 of the electrode layers. In some cases, dielectric layers 4 have dielectric constant K1 (e.g., dielectric constant value K1). In some cases, constant K1 may be a dielectric constant for the material between adjacent ones of electrode layers 2 and 3, such as a dielectric constant between adjacent ones of one of layer 2 and one of layer 3. In some cases, each of layers 4, all of layers 4, or at least the top half of layers 4 have dielectric constant K1. Dielectric layers 4 have vertical thickness T1. In some cases, thickness T1 may be a vertical thickness between adjacent ones of electrode layers 2 and 3, such as a thickness between adjacent ones of one of layer 2 and one of layer 3. In some cases, each of layers 4, all of layers 4, or at least the top half of layers 4 have thickness T1. In some cases, MLCC 1 has upper portion 22 having one of dielectric layers 4 separating or between each pair of adjacent electrode layers 2 and 3.

In some embodiments, the conductive electrode layers 2 and 3 are attached to conductive regions 5 and 6, respectively, which are attached to terminals 7 and 8 (e.g., contacts of the capacitor), which can be electrically attached to contacts 17 and 18 of the PCB 9, respectively. Specifically, first set of upper electrode layers 2 may be directly connected (e.g., touching and/or electrically conductively connected) to terminal 7 (and not terminal 8) of the MLCC via conductive region 5 (and not region 6) that extends along a left side of the MLCC. Second set of upper electrode layers 3 may be directly connected (e.g., touching and/or electrically conductively connected) to terminal 8 (and not terminal 7) of the MLCC via conductive region 6 (and not region 5) that extends along a right side of the MLCC.

FIGS. 1A and 1B also show MLCC 1 having second (e.g., lower) conductive electrode layers (e.g., set of lower layers 12 and 13) in bottom portion 23 of the MLCC. First set of the lower electrode layers 12 are directly connected to first terminal 7 (and not second terminal 8) of the MLCC via (e.g., attached or electrically connected through) a lower portion of first conductive region 5 (and not region 6) that extends along a left side of the MLCC. Second set of the lower electrode layers 13 are directly connected to second terminal 8 (and not first terminal 7) of the MLCC via a lower portion of second conductive region 6 (and not region 5) that extends along a right side of the MLCC. In some cases, these connections are a similar type of attachments as described above for the upper layers 2, region 5 and terminal 7. The vertical order or sequence of lower layers 12 and 13 may be interleaved or alternating as shown in the figure. They may be vertically interleaved or alternating with one dielectric layer 14 separating (or between each of) the layers 12 and 13 (e.g., each of an adjacent pair of a layer 12 and 13).

MLCC 1 has lower insulating low dielectric constant dielectric layers 14 separating the second electrode layers (e.g., disposed between layers 12 and 13), such as by having layers 14 between pairs of the first set 12 and second set 13 of the electrode layers. In some cases, dielectric layers 14 have dielectric constant K2 (e.g., dielectric constant value K2). In some cases, constant K2 may be a dielectric constant for the material between adjacent ones of electrode layers 12 and 13, such as a dielectric constant between adjacent ones of one of layer 12 and one of layer 13. In some cases, each of layers 14, all of layers 14, or at least the bottom half of layers 14 have dielectric constant K2. In some cases, dielectric layers 14 also have vertical thickness T1 (e.g., the same vertical thickness as layers 4). In some cases, thickness T1 may be a vertical thickness between adjacent ones of electrode layers 12 and 13, such as a thickness between adjacent ones of one of layer 12 and one of layer 13. In some cases, each of layers 14, all of layers 14, or at least the bottom half of layers 14 have thickness T1. In some cases, MLCC 1 has lower portion 23 having one of dielectric layers 14 separating or between each pair of adjacent electrode layers 12 and 13. According to some embodiments, K2 is less than K1.

Although the concepts described herein are with respect to embodiments of a MLCC (e.g., MLCC 1), an MLCC provides one example of a multi-layer capacitor, and the concepts described herein (e.g., of having upper and lower portions with different dielectric layer materials to reduce acoustic vibration) may be applied to other multi-layer capacitors having other dielectric material(s) (e.g., that are not ceramic material). In some cases, a MLCC is just one embodiment of a multi-layer capacitor, and the concepts described herein may apply to other multi-layer capacitors where layers 4 or 14 are not ceramic material. In some cases, the concepts described herein may apply to other multi-layer capacitors where layers 4 and 14 are not ceramic materials.

Conductive electrode layers 2, 3, 12 and 13 may be or include electrical conductor materials such as metal, alloy, copper, gold, silver, other conductors and/or combinations thereof, such as those known in the art for a MLCC. Also, regions 5 and 6; terminals 7 and 8; and contacts 17 and 18 may also be or include electrical conductor materials such as metal, alloy, copper, gold, silver, other conductors and/or combinations thereof, such as those known in the art for a MLCC. In some cases, region 5 and terminal 7, and/or region 6 and terminal 8 are formed of the same material or are formed at the same time and of the same material.

In some embodiments, dielectric layers 4 may be or include electrical dielectric (e.g., electrically insulating) materials such as a class 2 ceramic material (i.e., X5R/X7R) with typically high dielectric constant and high piezoelectric voltage coefficient. In some cases, all of the material dielectric layers 4 may be an X5R class dielectric, or a X7R class dielectric. In some embodiments, dielectric layers 4 may be or include electrical dielectric or insulating materials such as ferroelectric electrostrictive (e.g., possibly also described as electro-constrictive) materials, BaTiO3, an X5R class dielectric, a X7R class dielectric, another class 2 dielectric, and/or a combination thereof, such as those known in the art for a MLCC. These dielectric layers may be layered between the pairs of conductive electrode layers.

In some embodiments, dielectric layers 4 may be a class 2 ceramic dielectric material that has a high permittivity and therefore a better volumetric efficiency than layers 14, but lower accuracy and stability than layers 14. Layers 4 may be characterized by a nonlinear change of capacitance over the temperature range (and that may also depend on the applied voltage) as compared to layers 14. Layers 4 may exhibit more microphony than layers 14. In some embodiments, dielectric layers 4 may be ceramic capacitors and may be or include ferroelectric materials such as barium titanate (BaTiO3) and suitable additives such as aluminum silicate, magnesium silicate and aluminum oxide. In some embodiments, dielectric layers 4 may be (e.g., known as) X8R, X7R, X5R, X7S, Y5V, or Z5U. In some embodiments, dielectric layers 4 may be a mixture thereof.

In some embodiments, dielectric layers 14 may be or include electrical dielectric or insulating materials such as a class 1 ceramic material (i.e., P100 and C0G/NP0); or class 2 ceramic material with low dielectric constant and low piezoelectric voltage coefficient (i.e., d13 and d33). In some cases, all of the material of dielectric layers 14 may be a P100 class dielectric, a C0G class dielectric, or a NP0 class dielectric. In some cases, all of the material of dielectric layers 14 may be a class 2 dielectric with a low dielectric constant (e.g., below that of layers 4 for the same capacitor) and a low piezoelectric voltage coefficient of d13 or d33 (e.g., a low piezoelectric coefficient, Piezoelectric Modulus, or piezoelectric charge constant). In some embodiments, dielectric layers 14 may be or include electrical dielectric or insulating materials such as paraelectric (e.g., possibly described as non-electro-constrictive) materials, a P100 class dielectric, a C0G class dielectric, a NP0 class dielectric, a class 2 dielectric with low dielectric constant and low piezoelectric voltage coefficient of d13, a class 2 dielectric with low dielectric constant and low piezoelectric voltage coefficient of d33, and/or a combination thereof. These dielectric layers may be layered between the pairs of conductive electrode layers.

In some embodiments, dielectric layers 14 may be a class 1 ceramic dielectric material that is more accurate and temperature-compensating capacitors as compared to dielectric layers 4. They may offer the most stable voltage, temperature, and to some extent, frequency than layers 4. In some embodiments, dielectric layers 14 may be ceramic capacitors and may be or include a mixture of finely ground granules of paraelectric materials such as Titanium dioxide (TiO₂), modified by additives of Zinc, Zirconium, Niobium, Magnesium, Tantalum, Cobalt or Strontium (which may be necessary to achieve the capacitor's desired linear characteristics). In some embodiments, dielectric layers 14 may be MgNb₂O₆, ZnNb₂O₆, MgTa₂O₆, ZnTa₂O₆, ZnMg, TiO₃, ZrSn, TiO₄, or Ba₂Ti₉O₂₀. In some embodiments, dielectric layers 14 may be a mixture thereof.

In some embodiments, layers 4 and 14 are both a known dielectric ceramic material so that they bond at an interface between the materials (e.g., shown by the dashed like of FIG. 1A). In some cases, they are both a ceramic material that is a mixture of finely ground granules of paraelectric, ferroelectric or other known dielectric forming materials. In some cases, they are both Poly-4-vinylphenol, also called polyvinylphenol (e.g., PVP). In other cases, there are both doped materials so that they bond strongly at the interface. In other cases, there are both other similar materials, such as glass, porcelain, paper or mica so that they bond strongly at the interface.

Processes for forming layers 14 and layers 4 may include those know for forming MLCCs, such as for forming a ceramic MLCC. In some cases, those processes may include processes for forming lower portion 23 (e.g., with layers 14) and then forming (e.g., depositing onto, sintering onto, bonding onto, growing onto, or otherwise mating) portion 22 on top of portion 23 (or vice versa). This may include an interface (e.g., see the dotted line in FIG. 1A) including a corresponding portion of a bottom most one of one of layers 4 attached to (e.g., formed directly onto or touching) a corresponding portion of a top most one of layers 14. The corresponding portions may be where electrodes 2, 3 12 and 13 do not exist. In some cases, this may include an interface (not shown) including all of a bottom most surface of one of one of layers 4 attached to (e.g., formed directly onto or touching) all of a top most surface of one of layers 14.

In some cases, one of (e.g., a topmost) dielectric layers 4 forms a top surface of the capacitor, one of (e.g., a bottommost) dielectric layers 14 forms a bottom surface of the capacitor, and a second one (e.g., a bottommost) of layers 4 forms an interface (e.g., see the dotted line of FIG. 1A) with a second one (e.g., a topmost) of layers 14. In some cases, layers 4 extend from a top surface (e.g., top most layer) of the capacitor or just under a top cover material of the capacitor to an interface with layers 14; and layers 14 extend from a bottom surface (e.g., bottom most layer) of the capacitor or just above a bottom cover material of the capacitor to the interface with layers 4.

In some cases, MLCC 1 only includes upper portion 22 and lower portion 23, without other electrode and dielectric layers. In some cases, upper portion 22 is the topmost portion and lower portion 23 is the bottommost portion of MLCC 1. In some cases, there may be no other electrode layers (whether connected or not connected to the first or second terminal) and dielectric layers above portion 22 or below portion 23.

In some cases, MLCC 1 is divided into only upper portion 22 and lower portion 23, and has no other electrode or dielectric layers above portion 22 or below portion 23. In some cases, upper portion 22 is the topmost part of and includes the top surface of the MLCC 1; and lower portion 23 is the bottommost part of and includes the bottom surface of MLCC 1.

In some cases, MLCC 1 is divided into only upper portion 22 and lower portion 23, and has no other electrode or dielectric layers between portion 22 and portion 23. In some cases, upper portion 22 includes the top surface of the MLCC1, lower portion 23 includes the bottom surface of MLCC 1, and there are no other electrode layers (whether connected or not connected to the first or second terminal) between portion 22 and portion 23 (e.g., in the height H1 direction).

The material of layers 4 may extend to the top of the capacitor, and the material of layers 14 may extend to the bottom of the capacitor, with no other “cover” layers at the top and bottom. In these cases, for H1, the capacitor may have a maximum capacitance due to layers 4 and 14 extending all of height H1, without other layers that do not contribute to capacitance of the capacitor. In these cases, for H1, the capacitor may have a maximum capacitance due to height H1 only including (1) layers 4 of a higher dielectric in portion 22; and (2) layers 14 of relatively high, but low enough k dielectric K2 improve audio vibration as described herein.

Although other proposed solutions may include 3 or more portions having different dielectric layers having different dielectric constants. However, these solutions might sacrifice capacitance to solve the problem. For example, in some cases, these embodiments may not have a top portion of higher dielectric constant K1 dielectric having a height as tall as H3 (e.g., may not have layers 4 with constant K1 and height H3 but may be shorter than H3), and thus the capacitor will have less capacitance than a bi-layer capacitor described herein. In some cases, the bottom portion of the embodiments described herein may be sufficient to quiet a “singing” or “buzzing” capacitor; or reduce vibration that is transferred to the PCB by the capacitor such as through materials that bond bottom surface 11 to the capacitor to the PCB, without having more lower dielectric constant portions or without having more than two portions (e.g., without more than portions 22 and 23).

In some cases, the difference in dielectric layers from layer 14 to layer 4 is described as a “step change” that occurs at an interface between portions 22 and 23. Alternative embodiments consider other electrode and/or dielectric layers between upper portion 22 and lower portion 23. These other electrode and dielectric layers may include dielectric layers having a dielectric constant between K1 and K2. In some cases, one or more dielectric layers may exist here, formed of a mixture of the materials identified for layers 4 and 14. In some cases, these other dielectric layers may have a gradient in the dielectric constant between the upper and lower portion, such as where the constant gradually gets lower from the top to the bottom of the capacitor of the other layers between portions 22 and 23 by decreasing from K1 to K2. In some cases, a number of dielectric layers may exist here, formed of a mixture of the materials identified for layers 4 and 14, and decreasing from K1 to K2 going from layer 4 to layer 14.

In some cases, MLCC 1 has a front surface, as shown in FIG. 1A (e.g., a planar front vertical surface), and a back surface similar to the front surface (e.g., a planar back vertical surface). In some cases, conductive regions 5 and 6 may extend over a portion of the front and back surface of the capacitor. In some cases, they may extend over the front and back surfaces by a width equal to the width shown of the conductive regions extending over the top and bottom surfaces 15 and 16 in FIGS. 1A and 1B.

In some embodiments, one of the upper dielectric layers (e.g., topmost layer of layers 4 as shown in FIG. 1A) forms top surface 15 of the MLCC, and one of the lower dielectric layers (e.g., bottommost layer of layers 14 as shown in FIG. 1A) forms bottom surface 16 of the MLCC. Surfaces 15 and 16 may be exposed to the ambient, such as prior to mounting of the MLCC on a PCB or other device. In some case, the topmost dielectric layer of MLCC 1 that forms surface 15 may have dielectric constant K1 and thickness T1 (or another thickness appropriate for the top dielectric layer of MLCC 1).

Embodiments consider horizontally mounting the capacitor on a PCB or other surface, such as where base 10 or bottom surface 11 is mounted on a top surface or recess of a PCB. Such mounting may include solder, solder filler, resin, adhesive, or other materials as known in the art to connect the terminals of the capacitor to contacts, traces, or terminals of a PCB. It may also include those materials to bond bottom surface 11 to the PCB, etc.

In some cases, MLCC 1 includes bottom portion 10, which is configured to be mounted on a printed circuit board (PCB). Portion 10 may include terminals 7 and 8, and surface 16, which may have bottom surfaces for attaching to contacts and top surfaces of a PCB. In some embodiments, MLCC 1 is mounted on, attached to or connected to a PCB, such as by having terminals 7 and 8 electrically attached to contacts 17 and 18 (e.g., MLCC 1 is mounted on PCB 9 as shown in FIGS. 1A and 1B). This may include having terminals 7 and 8 electrically attached to contacts 17 and 18 by soldered, conductive adhesive to otherwise. This may include having base 10 or surface 16 of MLCC 1 attached, bonded or adhered to top surface 11 of the PCB 9.

In some embodiments, the conductive electrode layers 12 and 13 are attached to conductive regions 5 and 6, respectively, which are attached to terminals 7 and 8 (e.g., contacts), which can be electrically attached to contacts 17 and 18 of the PCB 9, respectively. Specifically, electrode layers 12 may be directly connected (e.g., touching and/or electrically conductively connected) to terminal 7 of the MLCC via conductive region 5 that extends along a left side of the MLCC. Electrode layers 13 may be directly connected (e.g., touching and/or electrically conductively connected) to terminal 8 of the MLCC via conductive region 6 that extends along a right side of the MLCC.

In other embodiments, MLCC 1 is not yet mounted on, attached to or connected to a PCB or other device (e.g., MLCC 1 is not mounted on PCB 9 as shown in FIGS. 1A and 1B). For example, MLCC 1 may be a separate component being provided for assembly or mounting onto a PCB, substrate, or other electronic component.

Layers 2, region 5 and terminals 7 may be used to receive or provide an input for a first signal to upper portion 22 of MLCC 1; while, at the same time, layers 3, region 6 and terminals 8 may be used to transmit or output (e.g., provide a response for upper portion 22 of MLCC 1 to) the same first signal received at terminal 7. In parallel and at the same time, layers 12, region 5 and terminal 7 may be used to receive or provide an input for a first signal to lower portion 23 of MLCC 1; while, at the same time, layers 13, region 6 and terminal 8 may be used to transmit or output (e.g., provide a response for lower portion 23 of MLCC 1 to) the same first signal received at terminal 7. It can be appreciated that these roles of terminals 7 and 8 can be reversed.

Such a first signal may include various differences in voltage and current such as by including various DC components, AC components, and polarities that change over time. This signal and these changes may exist between the first and second plurality of electrode layers. This signal and these changes may cause voltage gradients between the first and second plurality of electrode layers.

According to embodiments, in order to increase the capacitance of a MLCC, the number of dielectric layers in the MLCC (e.g., layers 4 and 14 of MLCC 1) can be increased. However, as the number of dielectric layers increases significantly (e.g., for the same height capacitor), the dielectric layer thickness between two adjacent electrode layers decreases to sub micrometer scale. In a case, where the dielectric layers are made from ferroelectric electrostrictive materials, such as BaTiO3, which is layered between conductive electrode layers, as the dielectric layer thickness decreases, the voltage gradient in the dielectric layer may polarize the dielectric materials and then induce the dielectric layers to deform (e.g., bend along the length of the layers) due to piezoelectric effects. The deformed MLCC generates a reaction force/moment, which acts on the PCB board (e.g., pushes a force into and away from PCB surface 11). Hence, the excited PCB board vibrates (e.g., in the vertical direction) due to the capacitor force/moment and induces the acoustic noise in the human hearing range (e.g., a vertical vibration in PCB 9 such as at or along surface 11). This may result in a “singing” or “buzzing” capacitor.

In some instances, such vibration is transferred to the PCB by direct contact or touching of terminal 7 and/or 8 and contacts or surfaces of the PCB. In some instances, such vibration is transferred to the PCB by through solder, solder filler, resin, adhesive, or other materials as known in the art to connect the terminals of the capacitor to contacts, traces, or terminals of a PCB. In some instances, such vibration is transferred to the PCB by through materials that bond bottom surface 11 to the PCB. In some instances, such vibration is transferred to the PCB by through any two or three of the above examples.

According to some embodiments, one efficient way to reduce the acoustic noise is to reduce the capacitor reaction force due to piezoelectric effects. The reaction force by the capacitor is mostly dominant by the bottom portion of layers a MLCC (e.g., lower portion 23). So, some embodiments of MLCC 1 (e.g., as shown and described for FIGS. 1A and 1B) are a bi-material dielectric layer capacitor for vibration and acoustic improvement (e.g., reduced vertical vibration). The embodiments may contain lower dielectric constant dielectric layers 14 (having thickness T1) at the bottom portion 23 of the capacitor to reduce the reaction force for vibration and provide acoustic improvement, and higher dielectric constant dielectric layers 4 (having thickness T1) at the top portion 22 of the capacitor for greater capacitance purpose. Such embodiments may have lower dielectric constant layers having a dielectric constant K2 such as between ⅓ and ⅔ times the dielectric constant K1 of the upper dielectric layers to reduce piezoelectric effect driven capacitor reaction forces on a printed circuit board (PCB) on which the capacitor is mounted. Such embodiments may include where K2 is at least 50% less than K1. Lower dielectric constant layers 14 reduce the reaction force for vibration and provide acoustic improvement due to their decreased dielectric constant reducing the voltage gradient polarized deformation of the dielectric layers due to piezoelectric effects. The resultant bi-material capacitor 1 has a significantly higher voltage rating without sacrificing an appreciable amount of capacitance, i.e., the voltage rating is improved.

In some embodiments, having thickness T1 that same for all of the dielectric layers 4 and 14 is not required, and those layers can have varying thicknesses. In some embodiments, the thickness of the upper and lower dielectric constant dielectric layers may vary from or not be equal to thickness T1. In some cases, some of those layers can have varying thicknesses. In some cases the variance may be within plus or minus 10 percent of T1. In other cases the variance may be greater than 10 percent and up to 100 percent. In some cases the variance is an expected but unintentional variance due to a formation process inaccuracy while attempting to form thickness T1. In other cases the variance is an intentional predetermined change to the thickness of one or more of the upper and/or lower dielectric constant dielectric layers. This case may include a thicker top and/or bottom layer of the capacitor, such as having a thickness of between T1 and 2×T1. In some cases, that thickness may be between 3×T1 and 5×T1.

In some embodiments, there are no dielectric “dummy layers” above or below layers 4 and 14. In some embodiments, there are no additional or other dielectric layers over a top layer of layers 4 or below a bottom layer of layers 14. In some cases, there is a single layer 4 above the topmost electrode of portion 22 (and no additional or other dielectric layers over a top layer of layers 4), and there is a single layer 14 below the bottom electrode of portion 23 (and no additional or other dielectric layers below a bottom most layer of layers 14).

In some cases, embodiments having layers 4 and 14 with different dielectric constants (as described herein) may also include dielectric layers 4 have a first vertical thickness between adjacent ones of electrode layers 2 and 3; dielectric layers 14 have a different, second vertical thickness between adjacent ones of electrode layers 12 and 13, and the second thickness is greater than the first thickness. These embodiments may also contain thicker dielectric layers 14 (e.g., a thickness T2 that is greater than T1) at the bottom portion 23 of the capacitor to reduce the reaction force for vibration and provide acoustic improvement, and the regular dielectric layers 4 (thickness T1) at the top portion 22 of the capacitor for greater capacitance purpose. Such embodiments may have lower dielectric layers having a vertical thickness T2 between 1.5 and 3.5 times thickness T1 of the upper dielectric layers to reduce piezoelectric effect driven capacitor reaction forces on a printed circuit board (PCB) on which the capacitor is mounted. Such embodiments may include where T2 is at least 50% greater than T1. Thicker dielectric layers 14 reduce the reaction force for vibration and provide acoustic improvement due to their increased thickness reducing the voltage gradient polarized deformation of the dielectric layers due to piezoelectric effects. The resultant bi-material dielectric layer capacitor 1 has an even more significantly higher voltage rating without sacrificing an appreciable amount of capacitance, i.e., the voltage rating is improved due to the benefit of both (1) having lower dielectric constant layers 14, and (2) having layers 14 with thickness T2 which is greater than T1.

More specifically, referring to FIGS. 1A and 1B, lower dielectric layers 14 may have a lower dielectric constant (K2) than a dielectric constant (K1) of the upper dielectric layers 4, such as to reduce piezoelectric effect driven capacitor reaction forces on printed circuit board (PCB) 9 on which the capacitor is mounted. According to some embodiments, lower dielectric layers 14 have a lower dielectric constant (K2) than a dielectric constant (K1) of the upper dielectric layers 4, such as to provide a larger range of frequency resonance or filtering for (e.g., between input and output of) MLCC 1. For example, the frequency response or electrical characteristics of MLCC 1 may be the combination or addition of that of the upper and lower portion. In addition, it is noted that the capacitance of MLCC 1 is the addition (e.g., aggregate) of the capacitance of the upper and lower portion since the upper and lower portion are electrically in parallel.

In some cases, embodiments may result in a higher voltage rating for all other things the same (e.g., number of capacitor layers), without sacrificing more than between 10 and 20 percent of the capacitance of the MLCC. In some cases, the voltage rating increases with increasing H3 and/or decreasing K2.

In some cases, portion 22 may have height H2 and portion 23 may have height H3. According to embodiments, width W1 may be approximately 1 mm. In some cases, height H1 may be approximately 0.6 mm. In some cases, height H3 may be 20 to 25% of height H1. In some cases, thickness T1 may be between 0.5 and 3 microns (e.g., ×10E-6 meters). In some cases, thickness T1 may be between 1 and 6 microns. In some cases, thickness K1 may be between 2 and 3 times the K2. Some embodiments may include any 3 of all 4 examples above.

According to embodiments, MLCC 1 may have between 300 and 400 total layers (e.g., for portion 22 and 23) of dielectric. This may include the sum of the number of layers 4 and 14. In some cases, MLCC 1 may have between 350 and 600 total layers of dielectric.

In some embodiments, K1 is above 1,000 and K2 is below 500. In some embodiments, K1 is above 500 and K2 is below 500. In some embodiments, K1 is between 1,000 and 1,900; and K2 is between 500 and 1,000. In some embodiments, K1 is between 1,000 and 3,000; and K2 is between 100 and 1,000. In some embodiments, K1 is between 500 and 1900; and K2 is between 1 and 500. In some embodiments, K1 is 1,000 and K2 is 500. In some embodiments, K2 is 50% of K1 (K2 is ½ of K1).

In some cases, H3 is less than 50 percent of the height of H1. In some cases, H3 is between 25 and 50 percent of H1. In some cases, H3 is between 25 and 30 percent of H1. In some cases, H3 is between 20 and 25 percent of H1. In some cases, H3 is approximately 25 percent of H1. In some cases, H3 is between 20 and 25 percent H1. In some cases, H3 is between 15 and 25 percent of H1. In some cases, H3 is between 15 and 20 percent of H1.

In some cases, the ratio of H3 to H1, the difference between (or ratio of) constants K1 to K2, and the number of layers in the upper and lower portion of the MLCC are factors to be considered in determining the reduction in audio vibration in the PCB due to the MLCC. Also, the ratio of height H3 to H1; width W1, height H1, and length L1 of the capacitor; the desired capacitance; and the desired frequency response of the capacitor may be factors for considering the difference between (or ratio of) constants K1 to K2. In some cases, the vertical thickness T1 may be a factor to be considered in determining the reduction in audio vibration in the PCB due to the MLCC. In some cases, the vertical thickness T1; the ratio of H3 to H1; the difference between constants K1 to K2; and the number of layers in the upper and lower portion of the MLCC are factors to be considered in determining the reduction in audio vibration in the PCB due to the MLCC.

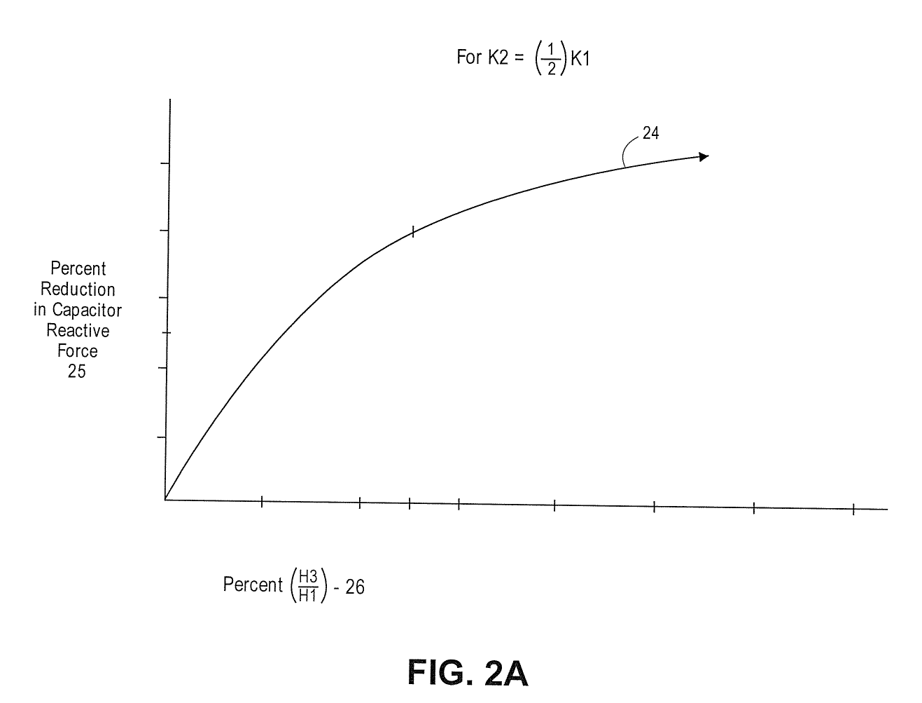

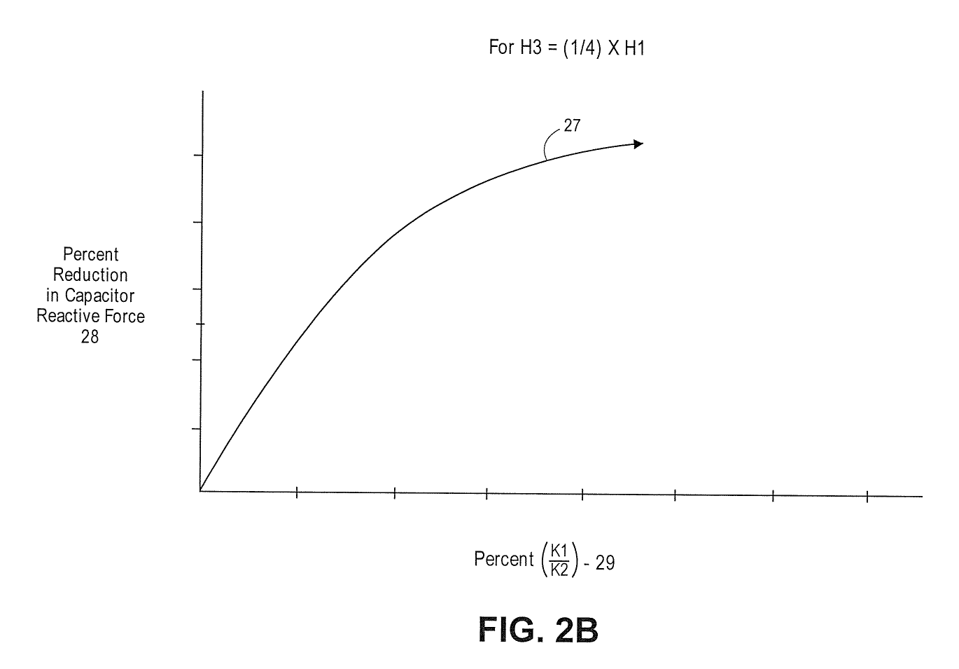

The difference in height H3 as compared to height H2 can be a factor for reducing audio vibration in the PCB due to the MLCC. FIG. 2A is an example of a plot of reduction in capacitor reaction force (e.g., in the audio frequency vibration of the PCB) versus the percentage of height H3 of the lower portion to total height H1 of a multi-layer capacitor (such as described herein for MLCC 1). FIG. 2A shows plot 24 of percent reduction in capacitor reactive force (CRF) 25 versus the percent (H3/H1) 26. CRF may be a force upon which audio vibration in the PCB is based or proportional. Plot 24 may be an estimated or predicted measurement of force 25 for vibrations in an audio range. In some cases, plot 24 may show an actual or peak measurement obtained by experimentation.

The CRF may exist or be described as a force between base 10 and surface 11 due to piezoelectric effects in dielectric layers 14 from voltage differences or polarity changes (e.g., AC in signals) at or between the second plurality of electrode layers 12 and 13. Such a CRF may exist or be described as a force between terminal 7 and/or 8 and contacts or surfaces of the PCB; through solder, solder filler, resin, adhesive, or other materials as known in the art to connect the terminals of the capacitor to contacts, traces, or terminals of a PCB; and/or through materials that bond bottom surface 11 to the PCB (e.g., surface 11) due to due to piezoelectric effects.

Plot 24 may be for an embodiment of an MLCC 1 where constant K2 is ½ or 50% of K1. Plot 24 may show a reduction of approximately 33%, where H3 is 25% or ¼ of the total of height H1. In some cases, for reduction in audio vibration of between 10 and 30% of the PCB, H3 may be 25% of H1. In some cases, for a reduction in audio vibration of between 30 and 40% of the PCB, H3 may be between 25% of H1.

Also, the difference in constant K1 as compared to constant K2 may be a factor for reducing audio vibration in the PCB due to the MLCC. FIG. 2B is an example of a plot of reduction in capacitor reaction force (e.g., in the audio frequency vibration of the PCB) versus the percentage of dielectric constant K1 of upper portion dielectric layers to constant K2 of the lower portion dielectric layers of a multi-layer capacitor (such as described herein for MLCC 1). FIG. 2B shows plot 27 of percent reduction and capacitor reactive force, CRF 28 versus percent (K1/K2) 29. Force 28 may be a force (e.g., a force between base 10 and surface 11 that is estimated, measured or otherwise) similar to the descriptions above for force 25.

FIG. 2B may be for a situation where height H3 is 25% or ¼ of height H1. Plot 27 may show a percent reduction of approximately 40% where K1 is three times K2. Plot 27 may also show a reduction of approximately 30% where K1 is twice K2. In some cases, K1 may be between 1.5 and 3.5 times K2. In some cases, K1 may be between 1.5 and 2.5 times, or between 2 and 3 times K2. For K1 that is 2 times K2 the vibration (e.g., CRF 28) may be reduced by 33%. For K1 that is 3 times K2 the vibration (e.g., CRF 28) may be reduced by 40%. However, these may be offset by the reduction in capacitance in portion 23 as compared to a same height of portion 22. For example, when K1 is two times K2, the capacitance of portion 23 may be 10% less than that of portion 22, for an equal thickness of the portions.

According to embodiments, between 75 and 80% of the capacitance of the MLCC for noise or vibration in the 1 to 10 kHz, or 1 to 20 kHz audio frequency range is in upper portion 22, such as when the capacitor is used to decouple a direct current (DC) signal from alternating current (AC) signal noise, in that range. Here however, only the other 25 to 20 percent of the capacitance in the audio range is in the lower portion 23.

In other words, top portion 22 decouples an AC signals in the audio range, while lower portion 23 does not or does to a minor extent. Thus, the audio range is decoupled from the DC signal output by the MLCC, but the vibration at that frequency, upon the PCB is reduced by approximately 33%, due to the existence of bottom portion 23 of the capacitor. Consequently, embodiments may be described as a capacitor having a dual resonance peak for frequencies based on constants K1 and K2, where the peak for K1 is in the audio range, but the peak for K2 is not.

In some cases, electrode layers 3 and dielectric layers 4 provide a first intended capacitance between the first terminal and the second terminal. This first intended capacitance may be in response to or as part of an electrical signal (e.g., electrical current and/or voltage) existing or transmitted between the terminals. This first intended capacitance may be an active or ideal capacitance based on first dielectric constant value K1 (and thickness T1, length L1, width W1, and number of layers in portion 22) that is in addition to any potential parasitic capacitance that exists at the terminals.

In some cases, electrode layers 13 and dielectric layers 14 provide a second intended capacitance between the first terminal and the second terminal. This second intended capacitance may be in response to or as part of an electrical signal (e.g., electrical current and/or voltage) existing or transmitted between the terminals. This second intended capacitance may be an active or ideal capacitance based on second dielectric constant value K2 (and thickness T1, length L1, width W1, and number of layers in portion 23) that is in addition to any potential parasitic capacitance that exists at the terminals. In some cases, electrode layers 3 and dielectric layers 4 create a first capacitance including a first ideal capacitance between terminals 5 and 6; and electrode layers 13 and dielectric layers 14 create a second capacitance including a second ideal capacitance between terminals 5 and 6.

In some cases, K2 (and optionally K1) are selected to reduce a downward force and vibration of MLCC 1 through solder and into an upper surface of a board or PCB upon which the capacitor is mounted. In some cases, K2 is (and optionally H3) are selected to reduce a capacitor reaction force due to piezoelectric effects in the second plurality of dielectric layers 14 from voltage differences or polarity changes (e.g., AC in signals) at or between the second plurality of electrode layers 12 and 13. In some cases, K2 is (and optionally H3 are) selected to reduce a vibration in the PCB due to the capacitor force in dielectric layers 14 from voltage differences or polarity changes (e.g., AC in signals) at or between the second plurality of electrode layers 12 and 13, inducing an acoustic noise in the human hearing range into the PCB. In some cases, K2 is (and optionally H3 are) selected to reduce a voltage gradient in the second dielectric layers (e.g., layers 12 and 13) from voltage differences or polarity changes (e.g., AC in signals) at or between the second plurality of electrode layers 12 and 13. In some cases, K2 is (and optionally H3 are) selected to reduce a deformation of the dielectric layers 14 due to piezoelectric effects in dielectric layers 14 from voltage differences or polarity changes (e.g., AC in signals) at or between the second plurality of electrode layers 12 and 13.

In some embodiments, bottom portion 23 has a height H3 equal to between 20 and 25 percent of a total height of the MLCC H1 (and height H2 is equal to H1 minus H3). In some embodiments, second constant K2 is between 500 and 1500. In some embodiments, second constant K2 is between 500 and 1500 less than the first constant K1. In some cases, the two embodiments above are combined. In some embodiments, bottom portion 23 has a height H3 equal to 25 percent of H1; and K2 is 1000 less than K1.

In some embodiments, height H3 is equal to between 20 and 30 percent of height H1 (and height H2 is equal to H1 minus H3). In some embodiments, (1) K1 is between 1000 and 3000; and K2 is between 100 and 1000; or (2) K1 is between 2 and 3 times K2. In some cases, the two embodiments above are combined. In some embodiments, height H3 is equal to between 20 and 30 percent of height H1; and K1 is between 1.5 and 2.5 times K2.

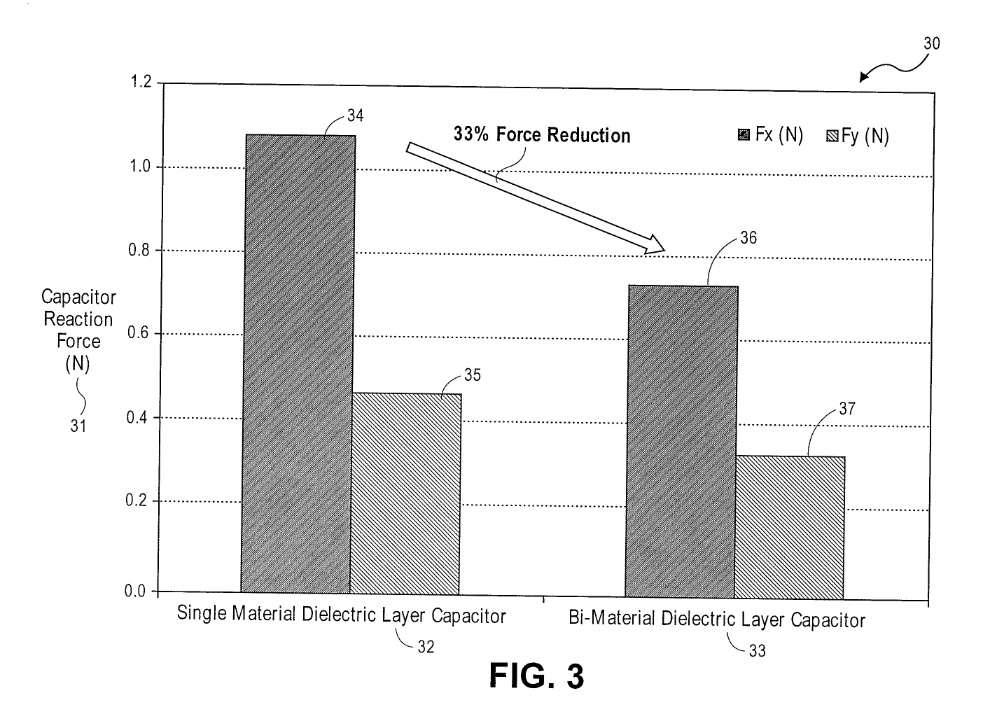

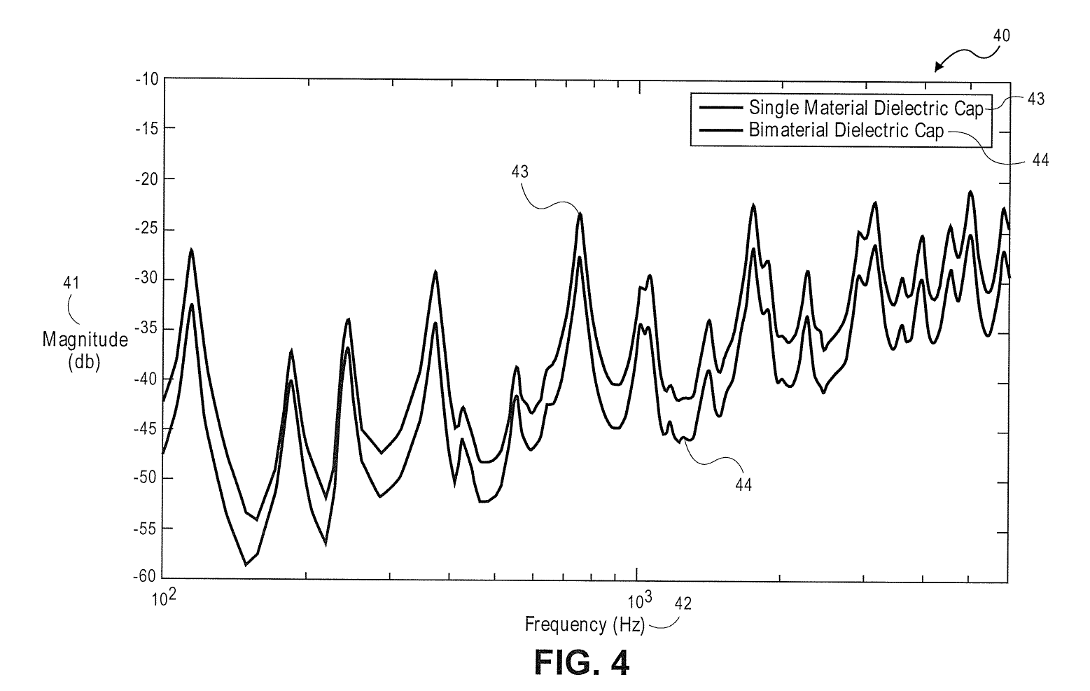

The simulation results shown in FIGS. 3-4 show examples that the bi-material dielectric layer capacitor (e.g., embodiments of MLCC 1) can reduce 33% more reaction force and then reduce the PCB board vibration and acoustic nose. In some case, the best vibration and acoustic performance improvement can be achieved by optimization of the bottom portion dielectric layer configuration (e.g., a combination of selecting H3/H1, and K2/K1).

FIG. 3 shows an example of capacitor reaction force for an example of a regular uniform dielectric layer capacitor and an example of a bi-material dielectric layer MLCC. FIG. 3 shows a graph of capacitor reaction force (CRF) 31 versus an example of a regular uniform dielectric layer capacitor 32 and a bi-material dielectric capacitor 33 (such as described herein for MLCC 1). Such a CRF (e.g., force 31) may be a force (e.g., a force between base 10 and surface 11 that is estimated, measured or otherwise) similar to the descriptions above for force 25.

In such an example, the regular uniform dielectric layer capacitor 32 may be similar to MLCC 1, except be a capacitor having only dielectric layers 4 (e.g., thickness T1) throughout a total height H1 of the capacitor. The bi-material dielectric capacitor 33 may be represented by embodiments described for MLCC 1.

FIG. 3 shows reaction forced 31 in Newtons (N) as compared to regular capacitor 32 and bi-material dielectric layer capacitor 33. For regular capacitor 32, bar graph 34 shows the reaction force in the X direction to be approximately 1.1 Newtons, and bar graph 35 shows the force in the Y direction to be approximately 0.45 Newtons. The X direction is presumed to be from left to right, or the length of the capacitor as (e.g., length L1) shown in FIGS. 1A and 1B; while the Y direction is presumed to be the width or direction into the page (e.g., width W1) of FIGS. 1A and 1B.

FIG. 3 shows force 31 for the bi-material capacitor 33 having force of bar graph 36 shown as approximately 0.72N in the X direction, and force of bar graph 37 shown as approximately 0.29N in the Y direction. It can be appreciated that the difference between the forces in the X direction is approximately 33% less for force 36 as compared to force 34.

It can be appreciated that for the forces in the Y direction, force 37 is approximately 33% less than force 35. Thus, according to some embodiments, use of the bi-material dielectric layer capacitor, or a capacitor having a second plurality of dielectric layers, that have a dielectric constant that is less than that of the first plurality, as described herein, may provide a 33% force reduction in both the X and Y directions. It can be appreciated that such a reduction in force may lead to a 33% reduction in the reaction force, which acts upon the PCB board and a 33% reduction in a force that pushes into and away from surface 11 of the PCB board. Hence, this reduction may result in about a 33% reduction of vibration of the PCB board, due to the capacitor force (e.g. force 31), and may result in a significant reduction in the acoustic noise in the human hearing range induced from the force 31 and/or board vibration that results from force 31.

FIG. 4 shows an example of PCB board frequency response for an example of a regular uniform dielectric layer capacitor and an example of a bi-material dielectric layer MLCC. FIG. 4 shows graph 40 plotting the PCB board frequency response for a bi-material dielectric layer capacitor (such as described herein for MLCC 1) as compared to a regular uniform layer capacitor. PCB board frequency response may be to measure the board vibration reaction due to the capacitor's reaction force. The capacitor can excite many PCB board modes (e.g., frequencies or frequency peaks). The PCB board frequency response may illustrate which board mode is more critical due to capacitor excitation. FIG. 4 shows capacitor can excite the critical PCB board mode to peak values at various frequencies between 100 Hz and 6 KHz, which are the modes with higher sound pressure levels.

Plot 40 shows magnitude 41 in Decibels (db), as compared to frequency 42 in db. The magnitude for a regular uniform layer capacitor is shown by plot 43, while the magnitude for a bi-material dielectric layer capacitor (such as described herein for MLCC 1) is shown by plot 44. This can be seen, the magnitude for 44 is approximately 5 db less for a bi-material dielectric layer capacitor, as compared to plot 43.

Consequently, this reduction may result in a 33% reduction of vibration of the PCB board, due to the magnitude (e.g., plot 44 over the frequency range), and may result in a 33% reduction in the acoustic noise in the human hearing range induced from the magnitude 44 and/or board vibration that results from magnitude 44.

Thus, embodiments have been described for providing devices of, systems including, and methods of forming and/or using a bi-material dielectric layer MLCC. For example, such a system may include MLCC 1 mounted on PCB 9. In some cases, such a method of forming a MLCC (e.g., MLCC 1) may include: forming first electrode layers in top portion 22 including forming layers 2 directly connected to terminal 7 (e.g., via region 5) and forming layers 3 directly connected to terminal 8 (e.g., via region 6); forming dielectric layers 4 separating the first electrode layers, wherein layers 4 have a vertical thickness T1 and a dielectric constant K1 between adjacent ones of the first electrode layers; forming second electrode layers in lower or bottom portion 23 including forming layers 12 directly connected to terminal 7 (e.g., via region 5) and forming layers 13 directly connected to terminal 8 (e.g., via region 6); and forming dielectric layers 14 separating the second electrode layers, wherein layers 14 have the vertical thickness T2 and a dielectric constant K2 between adjacent ones of the second electrode layers, wherein K2 is less than K1. In some cases, forming such MLCC may include selecting K1 and K2 to reduce a capacitor reaction force due to piezoelectric effects in layers 14 caused by or from the second electrode layers. In some cases, forming such and MLCC may include that one of layers 4 forms a top surface of the MLCC; and/or that one of layers 14 forms a bottom surface of the MLCC. In some cases, one of layers 4 forms a top surface, topmost portion, topmost layer, top cover, or top outer surface of the MLCC. In some cases, one of layers 14 forms a bottom surface, bottommost portion, bottommost layer, bottom cover, or bottom outer surface of the MLCC. In some cases, no further capacitance (e.g., intended capacitance) is provided by dielectric layers or electrode layers of the MLCC that exist above dielectric layers 4 and electrode layers 2 and 3. In some cases, no further capacitance (e.g., intended capacitance) is provided by dielectric layers or electrode layers of the MLCC that exist below dielectric layers 14 and electrode layers 12 and 13. In some cases, forming such an MLCC (or a system including MLCC 1) may include attaching the bottom surface or portion of the MLCC to a PCB (e.g., PCB 9), such as by attaching terminal 7 to contact 17, and attaching terminal 8 to contact 18. In some cases, such attaching may include (1) directly connecting layers 2 and 12 to terminal 7 via region 5; and (2) directly connecting layers 3 and 13 to terminal 8 via region 6. In some cases, forming such and MLCC may include selecting K2 to reduce a vibration in the PCB due to the capacitor force in layers 14 inducing an acoustic noise in the human hearing range. In some cases, forming such and MLCC may include (1) selecting K2 to reduce a voltage gradient in layers 14; and/or (2) selecting K2 to reduce a deformation of layers 14 due to piezoelectric effects in layers 14. In some cases it may also include selecting T1 to reduce a deformation of layers 14 due to piezoelectric effects in layers 14.

The embodiments provide benefits such as reducing instance of or avoiding the reactive force on a PCB board due to signals flowing through the MLCC, such as a force due to the piezoelectric forces caused by polarized ceramic or other dielectric materials in a capacitor, when such materials move or press upwards and downwards with a force, such as in response to an AC signal; a signal that increases or decreases in voltage; a signal that changes polarity; and the like. In some cases, the MLCC is considered to be discreet capacitors, such as a capacitor which is not part of (e.g., not formed as or in) the layers of a substrate or PCB, but is (or is to be) mounted on, soldered to, or otherwise attached to such a substrate or PCB.

The embodiments may also provide benefits such as reducing the vibration of the substrate or PCB (upon which the MLCC is mounted) resulting from the force on the substrate or PCB due to the piezoelectric forces, such as to reduce a vibration or acoustic, or audio signal or noise in the human hearing range, such as between 90 Hz and 20 kHz. The embodiments may also provide benefits such as reducing audio frequency “ring”, or “tuning out” audio resonance and vibration, within the human hearing range, such as at frequencies of less than 20 kHz.

Benefits of MLCC 1 include use of both layers 4 and 14 to provide active capacitance, such as parallel capacitive characteristics at terminals 7 and 8 for the capacitor. Benefits may also include using the lower portion dielectric layers and electrode layers to provide a varied capacitance electrical resonance frequency as compared to the upper layers.

The embodiments may also provide benefits such as not providing a MLCC that absorbs or resonates to many different frequencies (e.g., a large range of frequencies) outside of the audio range, but instead has a top portion that absorbs or resonates to frequencies including those in the audio range, and a bottom portion that absorbs or resonates to a frequency (or a number of frequencies) that are below (or optionally above) the audio range. In some cases, embodiments provide an MLCC bottom portion that “tunes out” or does not absorb (or cause a force on the PCB) in the frequency range of between 10 Hz and 10 kHz, or between 10 Hz and 20 kHz.

Embodiments of the invention can be applied to capacitors used in circuitry for filtering or otherwise passing various signals including power supply signals, AC signals, and DC bias signals. They can also be used in capacitors for handheld devices such as cellular phones, pad computers, and portable computers. They can also be used in capacitors for larger devices such as personal computers, client computers, and server computers.

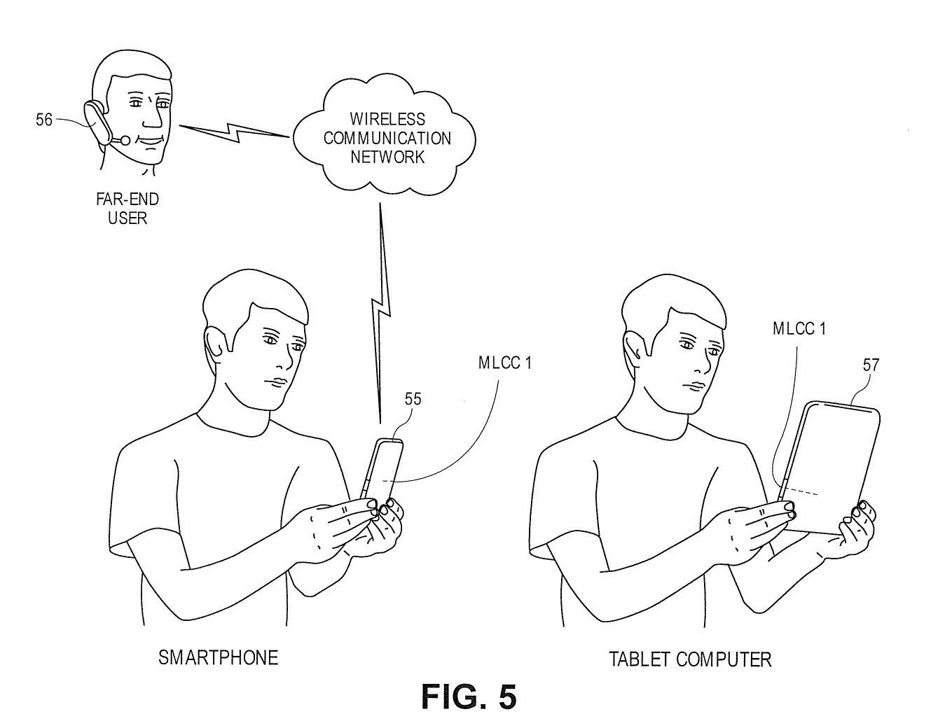

To conclude, various aspects of a multi-layer capacitor having bi-material dielectric layers have been described. As explained above, an embodiment of the invention may be housed in a portable device such as a mobile telephone communications device, a smart phone, a personal digital media player, a tablet computer, a notebook computer, and a compact desktop. For example, FIG. 5 depicts instances of portable consumer electronics devices in which embodiments of the invention may be implemented. As seen in FIG. 5, the multi-layer capacitor having bi-material dielectric layers (such as described herein for MLCC 1) may be included in a speakerphone unit that is integrated within a consumer electronic device 55 such as a smart phone with which a user can conduct a call with a far-end user of a communications device 56 over a wireless communications network. In another example, the multi-layer capacitor having bi-material dielectric layers may be mounted to a PCB that is integrated within the housing of tablet computer 57. These are just examples of where the bi-material dielectric layer capacitor may be used, it is contemplated, however, that the bi-material dielectric layer capacitor may be used with any type of electronic device in which it is desired to have a bi-material dielectric layer capacitor, such as in a lap top computing device or portable headset such as device 56.

While certain embodiments have been described and shown in the accompanying drawings, it is to be understood that such embodiments are merely illustrative of and not restrictive on the broad invention, and that the invention is not limited to the specific constructions and arrangements shown and described, since various other modifications may occur to those of ordinary skill in the art. For example, although embodiments of the bi-material dielectric layer capacitor described in FIGS. 1-5 include terminals 7 and 8 for direct horizontal mounting on PCB, other materials, layers, solder, adhesive, or electronic devices may exist between terminals 7 and 8 and contacts of the PCB. The description is thus to be regarded as illustrative instead of limiting.

What is claimed:

1. A multi-layer capacitor, comprising:
a first plurality of electrode layers in a top portion of the capacitor, a first set of the first plurality of electrode layers directly connected to a first terminal of the capacitor, and a second set of the first plurality of electrode layers directly connected to a second terminal of the capacitor;
a first plurality of dielectric layers separating the first plurality of electrode layers, wherein the first plurality of dielectric layers have a first dielectric constant value;
a second plurality of electrode layers in a bottom portion of the capacitor, a first set of the second plurality of electrode layers directly connected to the first terminal, and a second set of the second plurality of electrode layers directly connected to the second terminal; and
a second plurality of dielectric layers separating the second plurality of electrode layers, wherein the second plurality of dielectric layers have a second dielectric constant value;
wherein the second dielectric constant value is less than the first dielectric constant value.

2. The capacitor of claim 1, wherein the first plurality of dielectric layers have a first vertical thickness between adjacent ones of the first plurality of electrode layers; and wherein the second plurality of dielectric layers have the first vertical thickness between adjacent ones of the second plurality of electrode layers.

3. The capacitor of claim 1, the first plurality of electrode layers and the first plurality of dielectric layers to provide a first capacitance including a first ideal capacitance between the first terminal and the second terminal; and the second plurality of electrode layers and the second plurality of dielectric layers to provide a second capacitance including a second ideal capacitance between the first terminal and the second terminal.

4. The capacitor of claim 1, wherein one of (1) the second dielectric constant value is to reduce a capacitor reaction force due to piezoelectric effects in the second plurality of dielectric layers from the second plurality of electrode layers, or (2) the second dielectric constant value is selected to reduce a voltage gradient in the second plurality of dielectric layers from the second plurality of electrode layers.

5. The capacitor of claim 1, wherein the first and second dielectric constant values are selected to reduce a downward force and vibration of the capacitor through solder and into an upper surface of a board or printed circuit board (PCB) PCB upon which the capacitor is mounted.

6. The capacitor of claim 1, wherein the first plurality of dielectric layers have a first vertical thickness between adjacent ones of the first plurality of electrode layers, the second plurality of dielectric layers have a second vertical thickness between adjacent ones of the second plurality of electrode layers, and the second thickness is greater than the first thickness.

7. The capacitor of claim 1, wherein the capacitor is a multi-layer-ceramic-capacitor (MLCC), wherein a height of the bottom portion is equal to between 20 and 30 percent of a total height of the MLCC; and wherein a height of the top portion is equal to the total height of the MLCC minus the height of the bottom portion.

8. The capacitor of claim 7 wherein one of (1) the first dielectric constant value of the first plurality of dielectric layers is between 1000 and 3000; and the second dielectric constant value of the second plurality of dielectric layers is between 100 and 1000; or (2) the first dielectric constant value of the first plurality of dielectric layers is between 2 and 3 times the second dielectric constant value of the second plurality of dielectric layers.

9. The capacitor of claim 1, wherein one of the first plurality of dielectric layers forms a top surface of the capacitor; wherein one of the second plurality of dielectric layers forms a bottom surface of the capacitor; and wherein the bottom portion is configured to be mounted on a printed circuit board (PCB).

10. The capacitor of claim 1, wherein no further capacitance is provided by electrode layers or dielectric layers that exist in the capacitor above the first plurality of dielectric layers of the capacitor; and no further capacitance is provided by electrode layers or dielectric layers that exist in the capacitor below the second plurality of dielectric layers of the capacitor.

11. The capacitor of claim 1, wherein the first terminal is attached to a first contact of a printed circuit board (PCB), wherein the second terminal is attached to a second contact of the PCB, and wherein the second dielectric constant value is selected to reduce a vibration in the PCB due to the capacitor force, in the second plurality of dielectric layers from the second plurality of electrode layers, inducing an acoustic noise in the human hearing range.

12. The capacitor of claim 1, wherein the second dielectric constant value is selected to reduce a deformation of the second plurality of dielectric layers due to piezoelectric effects in the second plurality of dielectric layers from the second plurality of electrode layers.

13. The capacitor of claim 1, wherein the bottom portion has a height equal to between 20 and 30 percent of a total height of the capacitor; and wherein the first dielectric constant is between 1.5 and 2.5 times the second dielectric constant

14. A system comprising:
a printed circuit board (PCB); and
a multi-layer capacitor mounted on the PCB, the capacitor comprising
a first plurality of electrode layers in a top portion of the capacitor, a first set of the first plurality of electrode layers directly connected to a first terminal of the capacitor, and a second set of the first plurality of electrode layers directly connected to a second terminal of the capacitor,
a first plurality of dielectric layers separating the first plurality of electrode layers, wherein each of the first plurality of dielectric layers has a first dielectric constant value,
a second plurality of electrode layers in a bottom portion of the capacitor, a first set of the second plurality of electrode layers directly connected to the first terminal, and a second set of the second plurality of electrode layers directly connected to the second terminal, and
a second plurality of dielectric layers separating the second plurality of electrode layers, wherein each of the second plurality of dielectric layers has a second dielectric constant value;
wherein the second dielectric constant value is less than the first dielectric constant value.

15. The system of claim 14, wherein one of (1) the second dielectric constant value is to reduce a capacitor reaction force due to piezoelectric effects, or (2) the second dielectric constant value is selected to reduce a voltage gradient in dielectric layers of the capacitor.

16. The system of claim 14, wherein one of the first plurality of dielectric layers forms a top surface of the capacitor; wherein one of the second plurality of dielectric layers forms a bottom surface of the capacitor; wherein a second one of the first plurality of dielectric layers forms an interface with a second one of the second plurality of dielectric layers; wherein the first plurality of dielectric layers have a first vertical thickness between adjacent ones of the first plurality of electrode layer; wherein the second plurality of dielectric layers have the first vertical thickness between adjacent ones of the second plurality of electrode layers; and wherein the bottom portion is mounted on the PCB.

17. The system of claim 16, wherein the first terminal is attached to a first contact of the PCB, wherein the second terminal is attached to a second contact of the PCB, and wherein the second dielectric constant value is selected to reduce a vibration in the PCB inducing an acoustic noise in the human hearing range.

18. A method of forming a multi-layer capacitor, comprising:
forming a first plurality of electrode layers in a top portion of the capacitor, a first set of the first plurality of electrode layers directly connected to a first terminal of the capacitor;
forming a second set of the first plurality of electrode layers directly connected to a second terminal of the capacitor;
forming a first plurality of dielectric layers separating the first plurality of electrode layers, wherein the first plurality of dielectric layers have a first dielectric constant value;
forming a second plurality of electrode layers in a bottom portion of the capacitor, a first set of the second plurality of electrode layers directly connected to the first terminal;
forming a second set of the second plurality of electrode layers directly connected to the second terminal; and
forming a second plurality of dielectric layers separating the second plurality of electrode layers, wherein the second plurality of dielectric layers have a second dielectric constant value;
wherein the second dielectric constant value is less than the first dielectric constant value.

19. The method of claim 18, further comprising the first and second dielectric constant values to reduce a capacitor reaction force due to piezoelectric effects in the second plurality of dielectric layers from the second plurality of electrode layers.

20. The method of claim 18, wherein one of the first plurality of dielectric layers forms a top surface of the capacitor; wherein one of the second plurality of dielectric layers forms a bottom surface of the capacitor; wherein a second one of the first plurality of dielectric layers forms an interface with a second one of the second plurality of dielectric layers; and further comprising:
attaching the bottom portion to a printed circuit board (PCB).

21. The method of claim 20, wherein attaching comprises:
attaching the first terminal to a first contact of the PCB;
attaching the second terminal to a second contact of the PCB; and further comprising:
selecting the second dielectric constant value to reduce a vibration in the PCB due to the capacitor force, in the second plurality of dielectric layers from the second plurality of electrode layers, inducing an acoustic noise in the human hearing range.
